(19) United States
(12) Patent Application Publication
(10) Pub. No.: US 2026/0343853 A1
(43) Pub. Date: Oct. 29, 2026

(54) THREE-DIMENSIONAL SEMICONDUCTOR DEVICE

(71) Applicant: Samsung Electronics Co., Ltd., Suwon-si (KR)

(72) Inventors: Yujin Kim, Suwon-si (KR); Juhyun Kim, Suwon-si (KR); Hyeoncheol Kim, Suwon-si (KR); Bowon Yoo, Suwon-si (KR); Seunguk Han, Suwon-si (KR); Jinwoo Han, Suwon-si (KR)

(73) Assignee: Samsung Electronics Co., Ltd., Suwon-si (KR)

(21) Appl. No.: 19/460,153

(22) Filed: Jan. 26, 2026

(30) Foreign Application Priority Data
Apr. 29, 2025 (KR) 10-2025-0056429

(51) Int. Cl. H10B 12/00

(52) U.S. Cl. CPC H10B 12/30; H10B 12/03; H10B 12/05

(57) ABSTRACT

A three-dimensional semiconductor device comprises a substrate comprising a cell array region and an extension region, semiconductor patterns provided on the cell array region of the substrate and extending along a first direction substantially parallel to an upper surface of the substrate, word lines surrounding the semiconductor patterns and extending along a second direction substantially parallel to the upper surface of the substrate and substantially perpendicular to the first direction, an isolation structure extending along the second direction on the cell array region and the extension region, and a shield structure penetrating the isolation structure. The isolation structure is provided between the semiconductor patterns on the cell array region. The isolation structure and the shield structure each include a material different from one another.

### CROSS-REFERENCE TO RELATED APPLICATIONS

This present application claims priority to and the benefit under 35 U.S.C. § 119(a)-(d) of Korean Patent Application No. 10-2025-0056429, filed on Apr. 29, 2025, in the Korean Intellectual Property Office, the entire disclosure of which is incorporated herein by reference.

### FIELD

The present disclosure relates to a three-dimensional semiconductor device and method for manufacturing the same, and more particularly, to a three-dimensional semiconductor device with improved electrical characteristics.

### BACKGROUND

A semiconductor device is attracting attention as an important component in the electronics industry due to characteristics thereof such as miniaturization, multi-functionality, and/or low manufacturing cost. The semiconductor device may be classified into a semiconductor memory device that stores a logic data, a semiconductor logic device that calculates and processes the logic data, and a hybrid semiconductor device that includes a memory component and a logic component.

Recently, with a high speed and low power consumption of an electronic apparatus, a high operation speed, a low operation voltage and/or the like are/is also required for the semiconductor device built therein. In order to satisfy such requirements, a more highly-integrated semiconductor device is needed. However, when the semiconductor device becomes more highly-integrated, electrical characteristics and production yield of the semiconductor device may be reduced. Accordingly, much research for improving the electrical characteristics and the production yield of the semiconductor device is being carried out.

### SUMMARY

Embodiments of the disclosed concepts may provide a three-dimensional semiconductor device with improved electrical characteristics and reliability, and method for manufacturing the same.

According to embodiments of the disclosed concepts, a three-dimensional semiconductor device may comprise a substrate comprising a cell array region and an extension region, semiconductor patterns provided on the cell array region of the substrate and extending along a first direction substantially parallel to an upper surface of the substrate, word lines surrounding the semiconductor patterns and extending along a second direction substantially parallel to the upper surface of the substrate and substantially perpendicular to the first direction, an isolation structure extending along the second direction on the cell array region and the extension region, and a shield structure penetrating the isolation structure, wherein the isolation structure is provided between the semiconductor patterns on the cell array region, and wherein the isolation structure and the shield structure each include a material different from one another.

According to embodiments of the disclosed concepts, a three-dimensional semiconductor device may comprise a substrate comprising a cell array region and an extension region, semiconductor patterns provided on the cell array region of the substrate and extending along a first direction substantially parallel to an upper surface of the substrate, word lines surrounding the semiconductor patterns and extending along a second direction substantially parallel to the upper surface of the substrate and substantially perpendicular to the first direction, capacitor structures on one side of each of the semiconductor patterns, bit lines on the other side of each of the semiconductor patterns, an isolation structure extending along the second direction on the cell array region and the extension region and a shield structure penetrating the isolation structure, wherein at least a part of the shield structure overlaps with the extension region in a plan view.

According to embodiments of the disclosed concepts, a three-dimensional semiconductor device may comprise a substrate comprising a cell array region and an extension region, a semiconductor pattern extending along a first direction substantially parallel to an upper surface of the substrate, a word line surrounding the semiconductor pattern and extending along a second direction substantially parallel to the upper surface of the substrate and substantially perpendicular to the first direction, a bit line extending along a third direction substantially perpendicular to the upper surface of the substrate on a first edge portion of the semiconductor pattern, a capacitor structure on a second edge portion of the semiconductor pattern, an isolation structure extending along the second direction on the cell array region and the extension region and a shield structure penetrating the isolation structure, wherein the isolation structure comprises a first isolation structure provided adjacent to the first edge portion of the semiconductor pattern and a second isolation structure provided adjacent to the second edge portion of the semiconductive pattern, wherein the shield structure comprises a first shield structure extending into the first isolation structure and a second shield structure extending into the second isolation structure, and wherein the first isolation structure and the second isolation structure each include a material having an etch selectivity different from that of the first shield structure and the second shield structure.

According to embodiments of the disclosed concepts, a method of manufacturing a semiconductor device may include preparing a substrate including a first region and a second region, forming semiconductor patterns extending in a first direction on the first region of the substrate, forming an isolation structure extending in a second direction substantially perpendicular to the first direction across the first region and the second region between the semiconductor patterns, forming a shield structure penetrating the isolation structure, forming a word line extending in the second direction and surrounding the semiconductor patterns on the first region in the substrate, and forming a capacitor structure connecting with one side of the semiconductor pattern, wherein the shield structure may include a material having an etch selectivity different from that of the isolation structure.

According to embodiments of the disclosed concepts, forming the word line may include removing a portion of the isolation structure on the first region to form an open region, forming a conductive layer surrounding the semiconductor pattern on the first region, and patterning the conductive layer.

According to embodiments of the disclosed concepts, a method of manufacturing a three-dimensional semiconductor device may further comprise forming a gate connection line on the second region of the substrate prior to forming the capacitor structure, wherein forming the gate connection line may comprise removing a portion of the isolation structure on the second region to form an open region and forming the gate connection lines on the second region.

According to some embodiments, removing a portion of the isolation structure on the second region may include performing a wet etch process until one end of the shield structure is exposed.

According to some embodiments, forming the capacitor structure may include removing a portion of the semiconductor pattern and forming a capacitor structure on the semiconductor pattern.

### BRIEF DESCRIPTION OF THE DRAWINGS

FIG. 1 is a circuit diagram illustrating a three-dimensional semiconductor device according to some embodiments of the disclosed concepts.

FIGS. 2A, 2B, and 2C are perspective views of a three-dimensional semiconductor device according to some embodiments of the disclosed concepts.

FIG. 3 is a plan view illustrating a cell array region of a three-dimensional semiconductor device according to some embodiments of the disclosed concepts.

FIG. 4 is a cross-sectional view taken along line A-A′ of FIG. 3 according to some embodiments of the disclosed concepts.

FIG. 5 is a cross-sectional view taken along line B-B′ of FIG. 3 according to some embodiments of the disclosed concepts.

FIG. 6 is a cross-sectional view taken along line C-C′ of FIG. 3 according to some embodiments of the disclosed concepts.

FIG. 7 is a plan view illustrating a cell array region of a three-dimensional semiconductor device according to some embodiments of the disclosed concepts.

FIGS. 8, 9, 10, 11, 12, 13, 14, 15, 16, and 17 are cross-sectional views illustrating a process of fabricating a three-dimensional semiconductor device according to some embodiments of the disclosed concepts.

FIG. 18 is a plan view illustrating a cell array region of a three-dimensional semiconductor device according to some embodiments of the disclosed concepts.

FIG. 19 is a cross-sectional view taken along line D-D′ of FIG. 18 according to some embodiments of the disclosed concepts.

FIG. 20 is a cross-sectional view taken along line E-E′ of FIG. 18 according to some embodiments of the disclosed concepts.

### DETAILED DESCRIPTION

Example embodiments of the disclosed concepts will now be described more fully with reference to the accompanying drawings, in which example embodiments are shown.

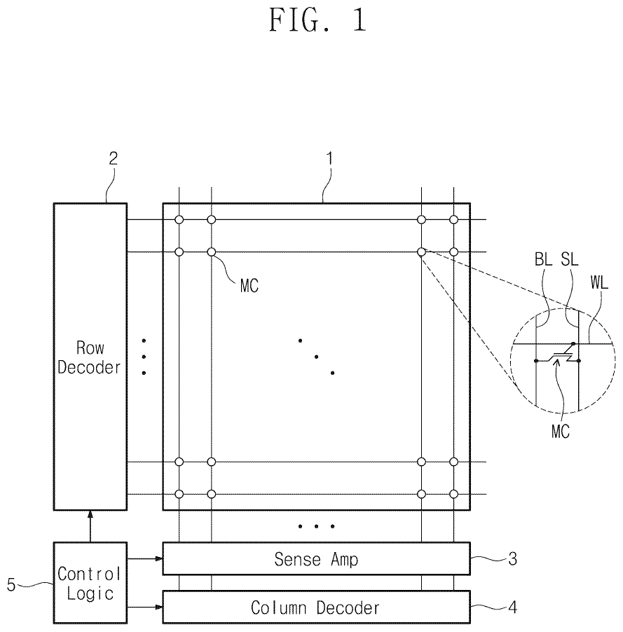

FIG. 1 is a circuit diagram illustrating a three-dimensional semiconductor device according to some embodiments of the disclosed concepts.

Referring to FIG. 1, the three-dimensional semiconductor device may include a memory cell array 1, a row decoder 2, a sense amplifier 3, a column decoder 4 and a control logic 5.

The memory cell array 1 may include word lines WL, bit lines BL, source lines SL and memory cells MC. The memory cells MC may be three-dimensionally arranged, and each of the memory cells MC may be connected to one word line WL, one bit line BL, and one source line SL. According to some embodiments, each of the memory cells MC may be composed of one transistor including a memory layer (or data storage layer).

The row decoder 2 may decode an address input from the outside and may select one of the word lines WL of the memory cell array 1. The address decoded by the row decoder 2 may be provided to a row driver (not shown), and the row driver may provide a voltage to a selected word line WL and unselected word lines WL in response to controlling of control circuits.

The sense amplifier 3 may sense, amplify and output a voltage difference between a selected bit line BL according to an address decoded by the column decoder 4 and a reference bit line.

The column decoder 4 may provide a data transfer path between the sense amplifier 3 and an external device (for example, a memory controller). The column decoder 4 may select any one among the bit lines BL by decoding an address input from the outside.

The control logic 5 may generate control signals that control operations of writing a data to the memory cell array 1 or reading the data from the memory cell array 1.

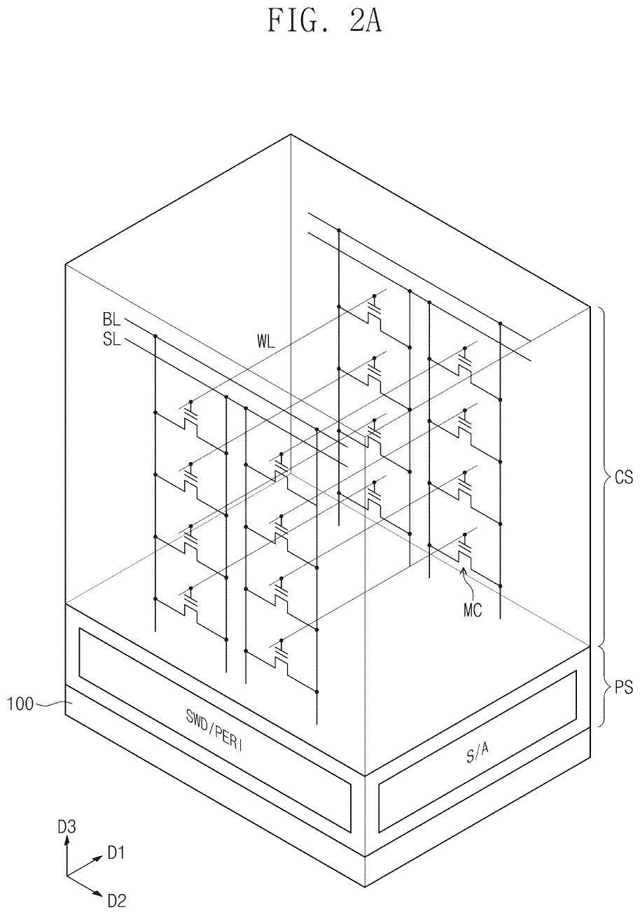

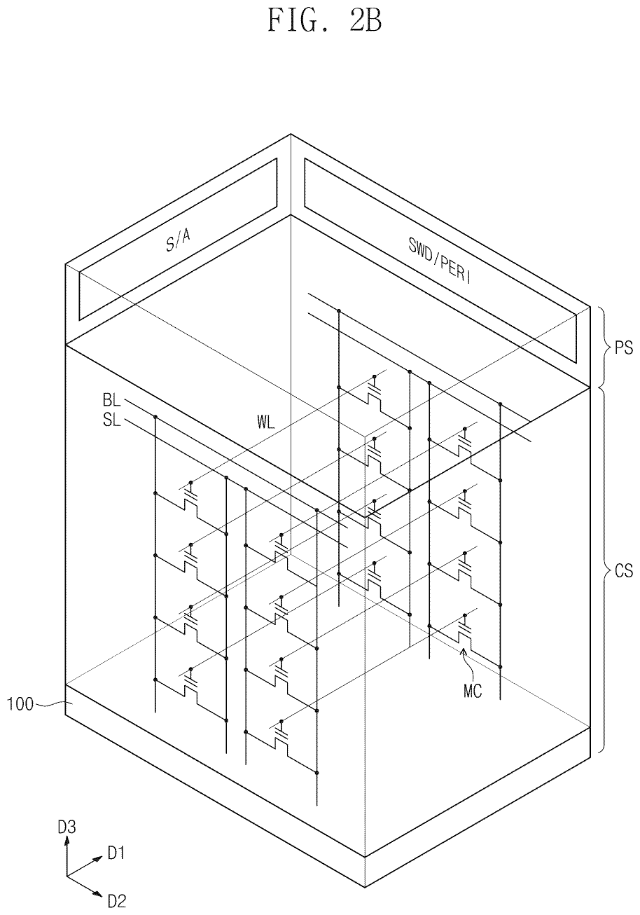

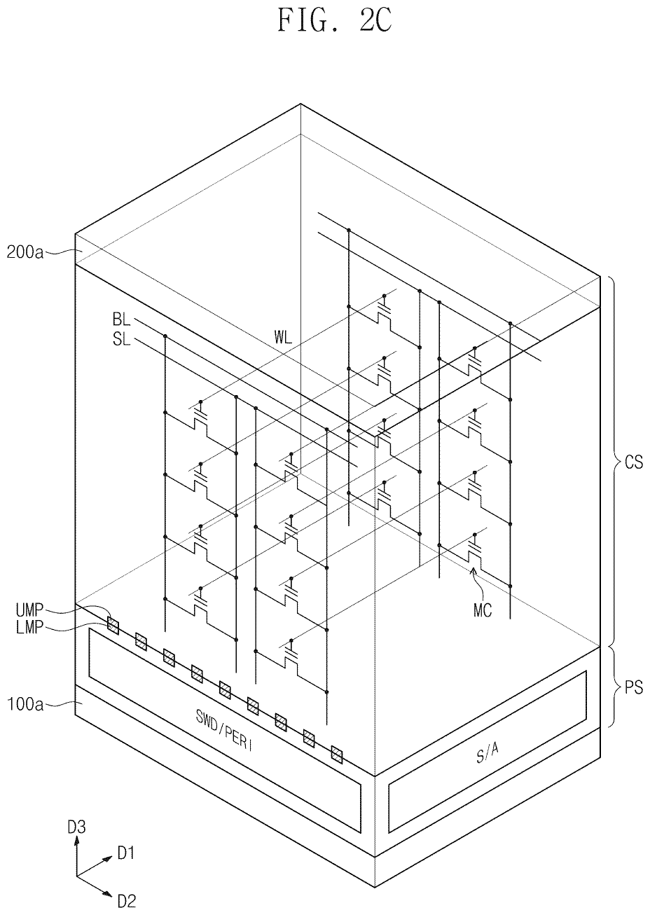

FIGS. 2A, 2B, and 2C are perspective views of a three-dimensional semiconductor device according to some embodiments of the disclosed concepts.

Referring to FIG. 2A, the three-dimensional semiconductor device may include a substrate 100, a peripheral circuit structure PS on the substrate 100 and a cell array structure CS on the peripheral circuit structure PS.

The peripheral circuit structure PS may include core and peripheral circuits formed on the substrate 100. The core and peripheral circuits may include the row and column decoders 2 and 4 (see FIG. 1), the sense amplifier 3 (see FIG. 1) and the control logic 5 (see FIG. 1) described with reference to FIG. 1.

The substrate 100 may have a shape of a plate expanding along a plane defined by a first direction D1 and a second direction D2. In this specification, the first direction D1 and the second direction D2 may be parallel to an upper surface of the substrate 100, and may cross one another. The peripheral circuit structure PS and the cell array structure CS may be sequentially stacked on the substrate 100 in a third direction D3 perpendicular to the upper surface of the substrate 100.

The cell array structure CS may include the bit lines BL, the source lines SL, the word lines WL and the memory cells MC therebetween. Each of the memory cells MC may be connected to one word line WL, one bit line BL and one source line SL.

Referring to FIG. 2B, the semiconductor device may include the cell array structure CS on the substrate 100, and the peripheral circuit structure PS on the cell array structure CS. The cell array structure CS may be disposed between the substrate 100 and the peripheral circuit structure PS. The peripheral circuit structure PS may include core and peripheral circuits.

Referring to FIG. 2C, the semiconductor device may have a chip-to-chip (C2C) structure. The peripheral circuit structure PS may include a first substrate 100a. Lower metal pads LMP may be provided on an uppermost portion of the peripheral circuit structure PS. The lower metal pads LMP may be electrically connected to the core and peripheral circuits. The lower metal pads LMP may be bonded to upper metal pads UMP of the cell array structure CS.

The cell array structure CS may include a second substrate 200a, and the upper metal pads UMP may be provided on a lowermost portion of the cell array structure CS. The upper metal pads UMP may be electrically connected to the bit lines BL, the source lines SL and the word lines WL. The upper metal pads UMP may be electrically connected to the memory cells MC.

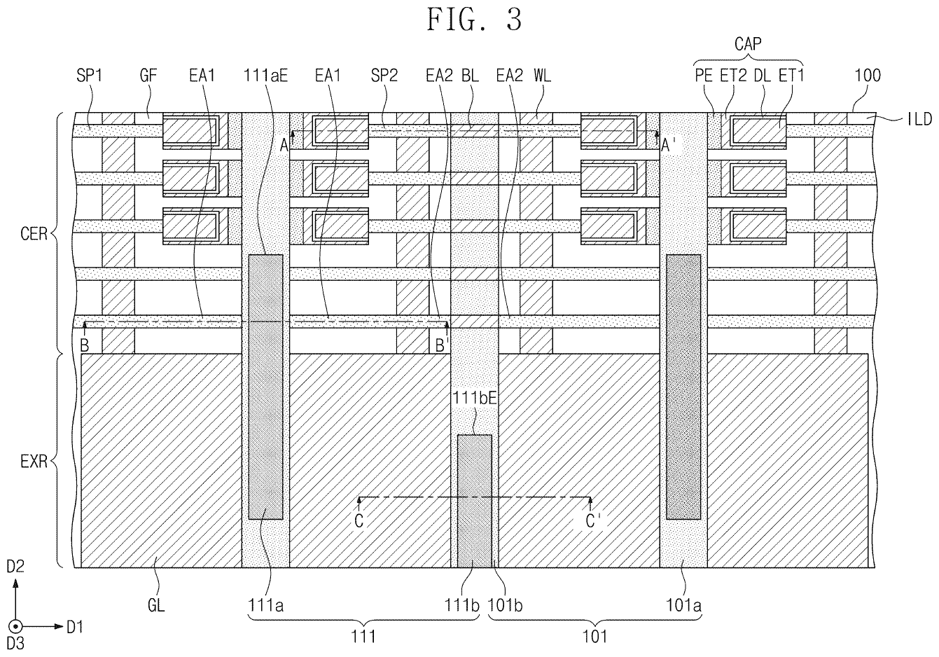

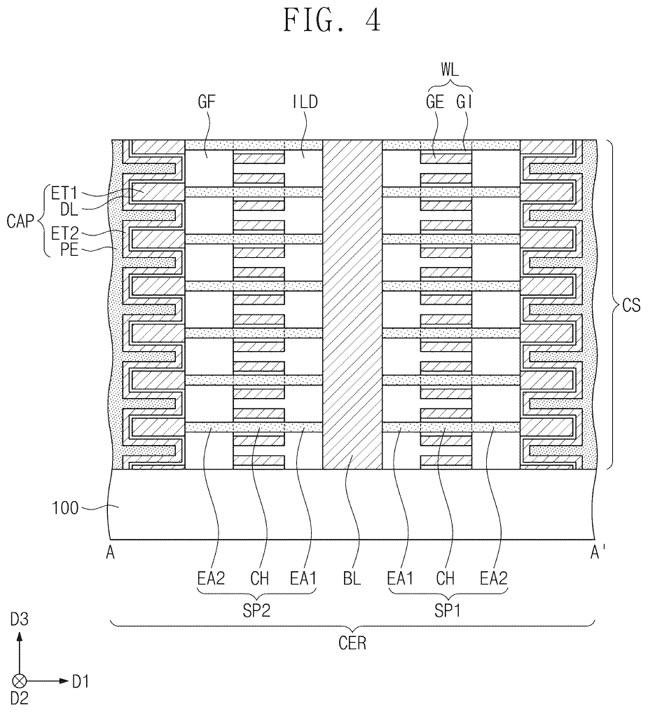

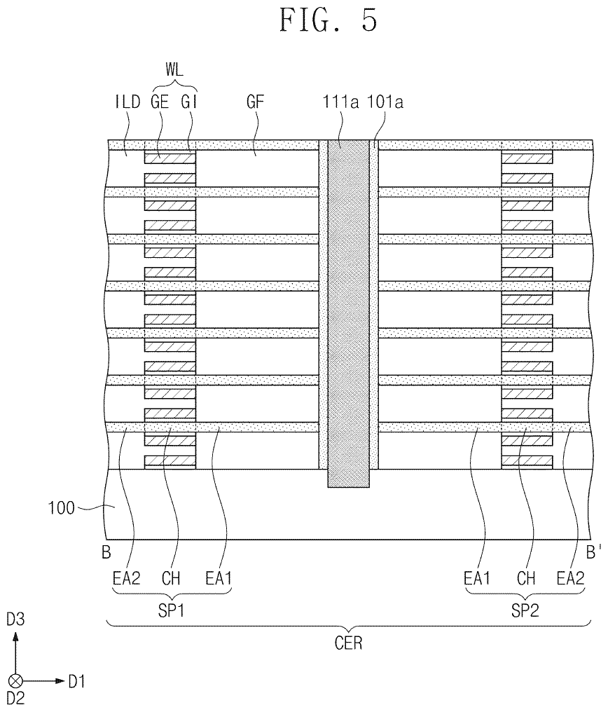

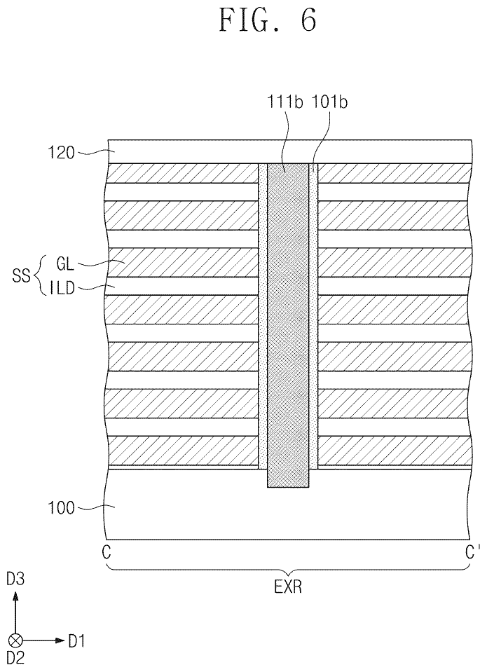

FIG. 3 is a plan view illustrating a cell array region of a three-dimensional semiconductor device according to some embodiments of the disclosed concepts. FIG. 4 is a cross-sectional view taken along line A-A′ of FIG. 3 according to some embodiments of the disclosed concepts. FIG. 5 is a cross-sectional view taken along line B-B′ of FIG. 3 according to some embodiments of the disclosed concepts. FIG. 6 is a cross-sectional view taken along line C-C′ of FIG. 3 according to some embodiments of the disclosed concepts.

Referring to FIGS. 3 to 6, a three-dimensional semiconductor device according to some embodiments of the disclosed concepts may include a substrate 100. The substrate 100 may be, for example, a semiconductor substrate. The semiconductor substrate may be, for example, a silicon substrate.

The substrate 100 may include a cell array region CER and an extension region EXR. The cell array region CER and the extension region EXR may be adjacent to one another in the second direction D2. In this specification, the cell array region CER and the extension region EXR may also be referred to as a first region and a second region.

As shown in FIG. 4, a cell array structure CS may be disposed on the substrate 100. In the FIG. 4, one cell array structure CS is shown on the substrate 100, but is not limited thereto. As an example, a plurality of cell array structures CS may be provided adjacent to one another in the first direction D1 or the second direction D2. Hereinafter, a single cell array structure CS will be described for convenience of description, but the following description may be equally applied to other cell array structures CS.

The cell array structure CS may include semiconductor patterns SP, word lines WL, and peripheral components surrounding them. Each will be described in detail below.

The semiconductor pattern SP may be spaced apart from the substrate 100 in the third direction D3. In other words, the semiconductor pattern SP may float from the substrate 100. The semiconductor pattern SP may extend along the first direction D1 on the substrate 100. As an example, the semiconductor pattern SP may have a shape of a bar extending along the first direction D1.

The semiconductor pattern SP may include at least one of a single crystal semiconductor, a polycrystalline semiconductor, an oxide semiconductor, or a two-dimensional material. As an example, the single crystal semiconductor may be a single crystal silicon. As an example, the polycrystalline semiconductor may be polysilicon. As an example, the oxide semiconductor may be Indium Gallium Zinc Oxide (IGZO). As an example, the two-dimensional material may be MoS2, WS2, MoSe2 or WSe2.

A plurality of semiconductor patterns SP may be provided. The semiconductor patterns SP may be disposed to be spaced apart from one another along the first direction D1 and the third direction D3. The semiconductor patterns SP disposed along the third direction D3 may vertically overlap one another. Sidewalls of the semiconductor patterns SP disposed along the third direction D3 may be aligned with one another.

The semiconductor pattern SP may include first semiconductor patterns SP1 and second semiconductor patterns SP2 provided to be spaced apart in the first direction D1 with respect to a bit line BL. The first semiconductor patterns SP1 may be disposed to be spaced apart from one another along the second direction D2 and the third direction D3. The second semiconductor patterns SP2 may be disposed to be spaced apart from one another along the second direction D2 and the third direction D3.

Each of the first semiconductor pattern SP1 and the second semiconductor pattern SP2 may include a first edge portion EA1 and a second edge portion EA2 spaced apart in the first direction D1, and a channel region CH therebetween. The channel region CH may overlap the word line WL in the third direction D3. The first edge portion EA1 may be connected to a bit line BL. The second edge portion EA2 may be connected to a capacitor structure CAP. As an example, each of the first and second edge portions EA1 and EA2 of the semiconductor pattern SP may include an impurity region doped with impurities (for example, an N-type or P-type impurity) therein. The impurity region may constitute a source/drain region of a transistor. In the present specification, the first edge portion EA1 and the second edge portion EA2 may also be referred to as one end or the other end of the semiconductor pattern SP.

The word line WL may surround the channel regions CH of the semiconductor patterns SP and extend along the second direction D2. A plurality of word lines WL may be provided. The word lines WL may be disposed to be spaced apart from one another in the third direction D3. In some other examples, the word line WL may extend on one side of the plurality of semiconductor patterns SP arranged along the second direction D2, and the cell array structure may include a single gate structure. In some other examples, the word line WL may include two elements each extending on an upper surface and a bottom surface of the plurality of semiconductor patterns SP arranged along the second direction D2, and the cell array structure may include a double gate structure.

At least one of the word lines WL may extend from the cell array region CER to the extension region EXR to constitute the gate connection line GL. Although not illustrated, the word lines WL extending to the extension region EXR may have a stepped structure in a cross-sectional view along the second direction D2. Although not shown, a contact may be connected to each end of the gate connection line GL forming the stepped structure. In embodiments, the word lines WL extending to the extension region EXR may not form a stepped structure, and the ends of the gate connection lines GL may be arranged and overlap along third direction D3.

The word line WL may include a gate insulating pattern GI surrounding the channel region CH of the semiconductor pattern SP and a gate electrode GE extending along the second direction D2 on the gate insulating pattern GI.

As an example, the gate electrode GE may be a single layer or a composite layer. As an example, the gate insulating pattern GI may include silicon oxide. As an example, the gate electrode GE may include at least one of Ti, TiN, TiSiN, TiON, W, WN, Mo, MoN, MoOxNy, Ta, TaN, Poly Si, Li, Na, K, Cs, Rb, Sr, Ba, Ca, Ce, Sm, Eu, Mg, Sc, Y, Hf, Tl, As, La, Nd, Gd, Tb, Lu, Th, U, Mn, Al, Ga, In, Pb, Cd, Bi, or Zr.

A bit line BL may be disposed between the first semiconductor patterns SP1 and the second semiconductor patterns SP2. The bit line BL may be provided on one side of the first semiconductor patterns SP1 and the second semiconductor patterns SP2. Specifically, the bit line BL may extend along the third direction D3 on the side surfaces of the first edge portions EA1 of the first semiconductor patterns SP1 and the first edge portions EA1 of the second semiconductor patterns SP2.

The bit line BL may be a single layer including one material or a composite layer including two or more materials. As an example, the bit line BL may include at least one of a metal material (e.g., Ti, Mo, W, Cu, Al, Ta, Ru, Ir, Co, or the like), a metal nitride (e.g., a nitride of Ti, Mo, W, Cu, Al. Ta, Ru, Ir, Co, etc.), or a metal silicide (e.g., silicide of Ti, Mo. W, Cu, Al, Ta, Ru, Ir, Co or the like).

An interlayer insulating layer ILD may be interposed between the word lines WL disposed to be spaced apart from one another in the third direction D3, and may separate them. The interlayer insulating layer ILD may be interposed between the semiconductor patterns SP disposed to be spaced apart from one another in the third direction D3.

A gap-fill layer GF may be interposed between the semiconductor patterns SP disposed to be spaced apart from one another in the third direction D3. The gap-fill layer GF may be provided between the word line WL and a capacitor structure CAP. The gap-fill layer GF may include, for example, an insulating material. According to some embodiments, the interlayer insulating layer ILD may be provided instead of the gap-fill layer GF.

The interlayer insulating layer ILD and the gap-fill layer GF may each include at least one selected from silicon oxide, silicon nitride, silicon oxynitride, or silicon oxycarbide.

The capacitor structure CAP may be provided on the other side of the first semiconductor patterns SP1 and the second semiconductor patterns SP2. Specifically, the capacitor structure CAP may be provided on the side surfaces of the second edge portions EA2 of the semiconductor patterns SP disposed to be spaced apart from one another along the third direction D3. That is, the capacitor structure CAP may be connected to the second edge portions EA2 of the semiconductor patterns SP.

However, the capacitor structure CAP may not be disposed on some of the semiconductor patterns SP adjacent to the extension region EXR. In this case, the length of the semiconductor pattern SP in the first direction D1 may be longer than the length of the other semiconductor pattern SP connected to the capacitor structure CAP in the first direction D1.

The capacitor structure CAP may include a first electrode ET1, a second electrode ET2, a dielectric layer DL, and a plate electrode PE covering them. A plurality of first electrodes ET1 may be provided, and may be spaced apart from one another in the third direction D3. The second electrode ET2 may be provided on the first electrode ET1, and the dielectric layer DL may be provided between the first electrode ET1 and the second electrode ET2. The first electrode ET1 and the second electrode ET2 may be spaced apart by the dielectric layer DL. The plate electrode PE may be provided on the second electrode ET2. As the capacitor structure CAP is provided, the three-dimensional semiconductor device according to embodiments of the disclosed concepts may be a dynamic random-access memory (DRAM).

Each of the first electrode ET1 and the second electrode ET2 may include a conductive material. As an example, each of the first electrode ET1 and the second electrode ET2 may include at least one of impurity-doped silicon (Si), impurity-doped silicon germanium (SiGe), a metal material (e.g., Ti, Mo, W, Cu, Al, Ta, Ru, Ir, Co, Pt, Au, Ag, etc.), a metal nitride (e.g., a nitride of Ti, Mo, W, Cu, Al. Ta, Ru, Ir, Co, Pt, Au, Ag, etc.), titanium silicon nitride (for example, TiSiN), titanium aluminum nitride (such as TiAlN), tantalum aluminum nitrides (such as TaAlN), a conductive oxide (for example, PtO, RuO₂, IrO₂, SRO (SrRuO₃), BSRO ((Ba,Sr)RuO₃), CRO (CaRuO₃), LSCo), or a metal silicide. Each of the first electrode ET1 and the second electrode ET2 may be a single layer made of a single material or a composite layer including two or more materials.

As an example, the dielectric layer DL may include at least one of a metal oxide such as HfO₂, ZrO₂, Al2O₃, La2O₃, Ta2O₃, and TiO₂, or a dielectric material having a perovskite structure such as SrTiO₃ (STO), (Ba,Sr)TiO₃(BST), BaTiO₃, PZT, and PLZT.

For another example, the capacitor structure CAP may may be a variable resistance pattern capable of being switched to two resistance states by an electrical pulse. In this case, the capacitor structure CAP may include a phase-change material changing a crystalline state according to an amount of current, a perovskite compound, transition metal oxide, a magnetic material, a ferromagnetic material or an anti-ferromagnetic material.

Although not shown, a silicide pattern may be provided between the first electrode ET1 and the semiconductor pattern SP. The silicide pattern may include metal silicide (for example, silicide of Ti, Mo, W, Cu, Al, Ta, Ru, Ir, Co or the like).

An isolation structure 101 may extend along the second direction D2 on the cell array region CER and the extension region EXR. The isolation structure 101 may be provided between adjacent semiconductor patterns SP in the first direction D1.

Specifically, the isolation structure 101 may include a first isolation structure 101a provided adjacent to the first edge portion EA1 of the semiconductor pattern SP and a second isolation structure 101b provided adjacent to the second edge portion EA2 of the semiconductor pattern SP. The first isolation structure 101a and the second isolation structure 101b may be spaced apart in the first direction D1. The number of the first isolation structure 101a and the second isolation structure 101b is not limited as shown.

On the cell array region CER, the first isolation structure 101a may be provided between the capacitor structures CAP spaced apart in the first direction D1. As shown in FIG. 5, the first isolation structure 101a may be provided on the first edge portion EA1 of the semiconductor pattern SP. On the cell array region CER, the bit line BL may penetrate the second isolation structure 101b.

The first isolation structure 101a and the second isolation structure 101b may include an insulating material. As an example, the first isolation structure 101a and the second isolation structure 101b may include silicon oxide.

A shield structure 111 may be provided that penetrates the isolation structure 101. In a plan view, at least a portion of the shield structure 111 may overlap the extension region EXR. The shield structure 111 may have a bar shape extending along the second direction D2. The shield structure 111 may be provided to be spaced apart from the bit line BL. In some embodiments, the shield structure 111 may include a portion disposed between two adjacent gate connection lines GL in the first direction D1.

The shield structure 111 may include a first shield structure 111a extending into the first isolation structure 101a and a second shield structure 111b extending into the second isolation structure 101b. That is, the first shield structure 111a may penetrate the first isolation structure 101a. The second shield structure 111b may penetrate the second isolation structure 101b.

Specifically, the first shield structure 111a may extend along the second direction D2 on the cell array region CER and the extension region EXR. The second shield structure 111b may extend along the second direction D2 on the extension region EXR.

In a plan view, a portion of the first shield structure 111a may overlap with the word lines WL along an arbitrary line extending in the first direction D1. The second shield structure 111b may overlap with the bit lines BL along an arbitrary line extending in the second direction D2. One end 111aE of the first shield structure 111a may be positioned closer to the capacitor structure CAP than one end 111bE of the second shield structure 111b.

In a plan view, one end 111aE of the first shield structure 111a may not be aligned with one end 111bE of the second shield structure 111b. In some embodiments, the plurality of first shield structures 111a and the plurality of second shield structures 111b may be alternately positioned along the first direction D1. In some embodiments, one ends 111aE of the plurality of first shield structures 111a may be located in the cell array region CER, and one ends 111bE of the plurality the second shield structures 111b may be located in an extension region EXR. In some embodiments, one ends 111aE of the plurality of first shield structures 111a and one ends 111bE of the plurality second shield structures 111b may be alternately arranged to be staggered with one another along the first direction D1.

The capacitor structure CAP disposed closest to the extension region EXR may be located farther from the extension region EXR than one end 111aE of the first shield structure 111a and one end 111bE of the second shield structure 111b.

That is, the capacitor structure CAP may not overlap the first shield structure 111a and the second shield structure 111b in a plan view. The first shield structure 111a may overlap the remaining semiconductor patterns SP among the semiconductor patterns SP that are not connected to the capacitor structure CAP in the first direction D1.

The height of the shield structure 111 may be greater than that of the isolation structure 101. As shown in FIGS. 5 and 6, the first shield structure 111a and the second shield structure 111b may extend into the substrate 100 through the first isolation structure 101a and the second isolation structure 101b. That is, the first shield structure 111a and the second shield structure 111b may each penetrate an upper portion of the substrate 100. From a horizontal perspective, the first isolation structure 101a may be provided between the gap-fill layer GF and the first shield structure 111a.

The first isolation structure 101a and the second isolation structure 101b may each include a material having an etch selectivity different from that of the first shield structure 111a and the second shield structure 111b. As an example, the first shield structure 111a and the second shield structure 111b may include silicon nitride.

Referring to FIG. 3 to 6, the substrate 100 of the three-dimensional semiconductor device according to some embodiments of the disclosed concepts may further include an extension region EXR adjacent to the cell array region CER in the second direction D2. The arrangement and design of the extension region EXR is not limited and may be freely changed and combined.

A connection structure SS may be disposed on the extension region EXR. The connection structure SS may include a plurality of gate connection lines GL and interlayer insulating layers ILD alternately stacked on the substrate 100. Each of the gate connection lines GL and the interlayer insulating layers ILD may extend along the first direction D1. Each of the gate connection lines GL of the connection structure SS may be connected to a gate electrode GE of each of the word lines WL of the cell array structure CS.

At least a portion of the shield structure 111 may overlap the gate connection line GL in the first direction D1. As an example, one end 111aE of the first shield structure 111a may be located between the capacitor structure CAP and the gate connection line GL. The other end of the first shield structure 111a may overlap the gate connection line GL.

The cover insulating layer 120 may cover the connection structures SS. The cover insulating layer 120 may include, for example, an insulating material.

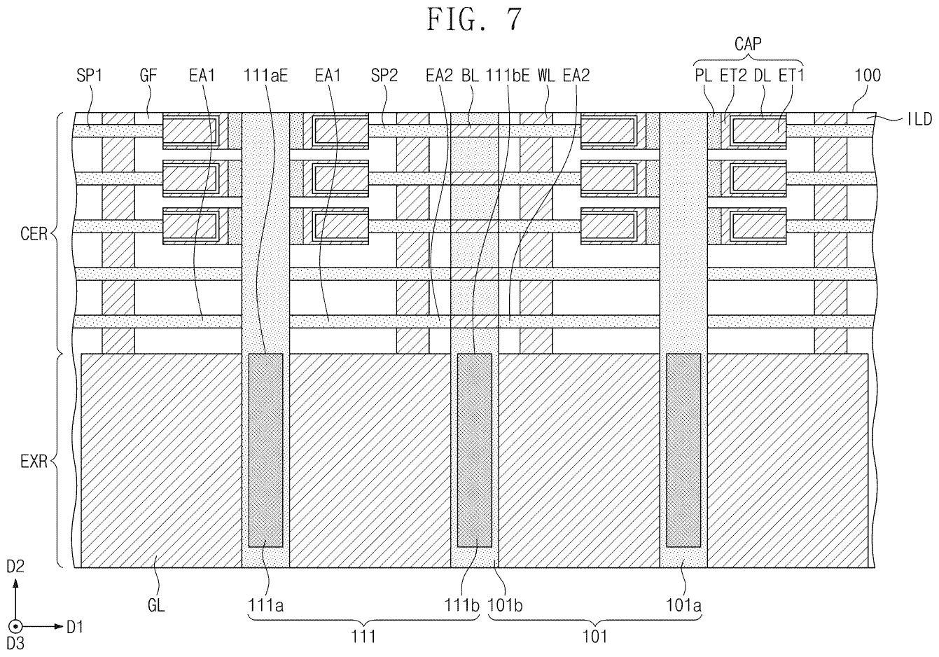

FIG. 7 is a plan view illustrating a cell array region of a three-dimensional semiconductor device according to some embodiments of the disclosed concepts.

Referring to FIG. 7, in some embodiments, the first shield structure 111a may not include a portion located in the cell array region CER. For example, the first shield structure 111a may not include a portion overlapping the first semiconductor pattern SP1 and the second semiconductor pattern SP2 in the first direction D1. One end of each of the shield structures 111 may be aligned in the first direction D1. In some embodiments, one end of each of the shield structures 111 may be aligned at a boundary between the extension region EXR and the cell array region CER.

Specifically, one end 111aE of the first shield structure 111a and one end 111bE of the second shield structure 111b may be aligned with an arbitrary line extending in the first direction D1 between the extension region EXR and the cell array region CER. That is, the first shield structure 111a and the second shield structure 111b may not extend on the cell array region CER.

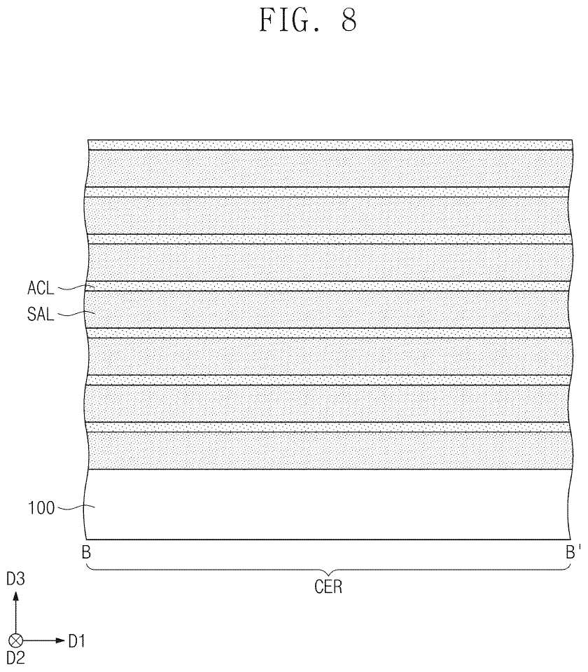

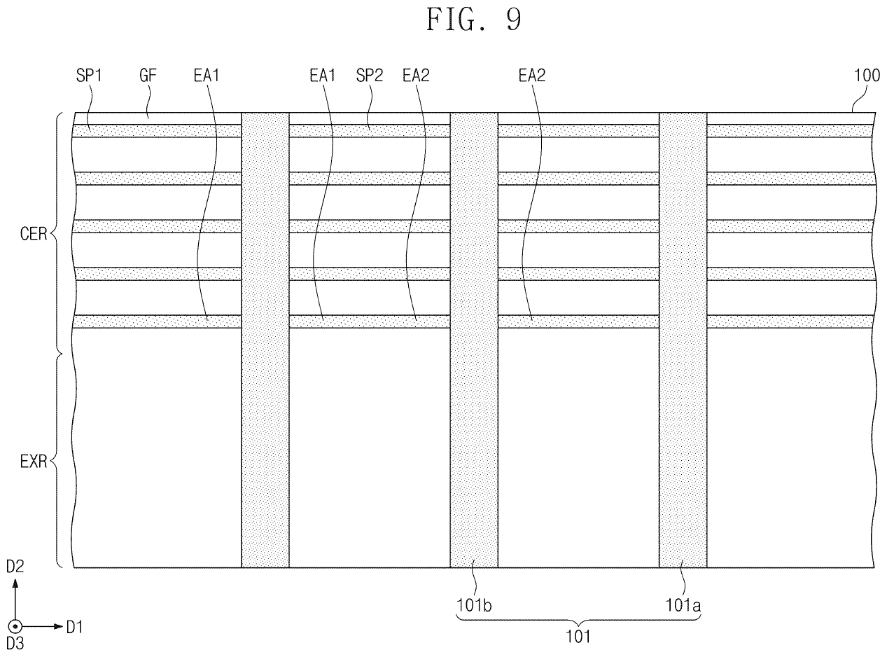

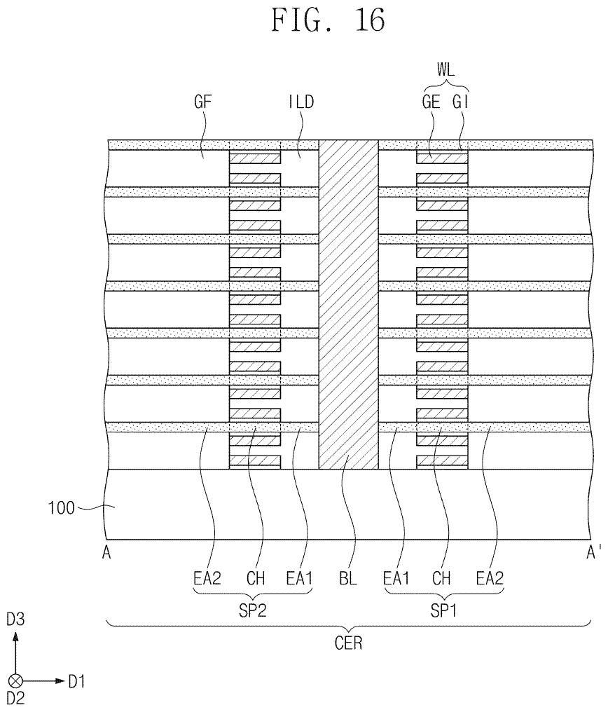

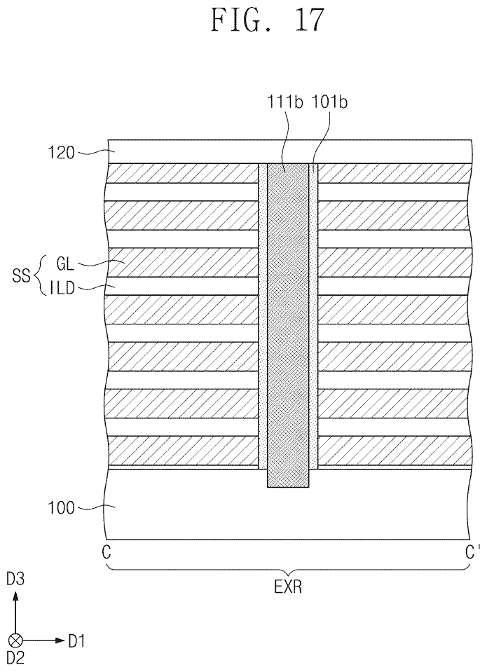

FIGS. 8, 9, 10, 11, 12, 13, 14, 15, 16, and 17 are cross-sectional views illustrating a process of fabricating a three-dimensional semiconductor device according to some embodiments of the disclosed concepts. Specifically, FIGS. 8, 10, 12, and 14 are cross-sectional views taken along line B-B′ of FIG. 3. FIG. 16 is a cross-sectional view taken along line A-A′ in FIG. 3. FIG. 17 is a cross-sectional view taken along line C-C′ in FIG. 3. FIGS. 9, 11, 13, and 15 are plan views corresponding to FIG. 3.

Referring to FIG. 8, a substrate 100 may be prepared. The substrate 100 may include a cell array region CER and an extension region EXR, as shown in FIG. 3. However, FIG. 8 only shows the cell array region CER.

Sacrificial layers SAL and Active layers ACL may be alternately stacked on the substrate 100. The sacrificial layers SAL and the active layers ACL may be formed over the cell array region CER and the extension region EXR. The sacrificial layers SAL and the active layers ACL may be formed by repeatedly performing an epitaxial process. Along the third direction D3, the thickness of the sacrificial layers SAL may be greater than the thickness of the active layers ACL, but is not limited thereto.

Each of the sacrificial layers SAL and the active layers ACL may include a semiconductor material. The sacrificial layers SAL may include a material that may have an etch selectivity with the active layers ACL. Accordingly, even if the sacrificial layers SAL are removed during the removal process of the sacrificial layers SAL, the active layers ACL may not be removed or may be removed in a small amount. As an example, the active layers ACL may include silicon, and the sacrificial layers SAL may include silicon-germanium.

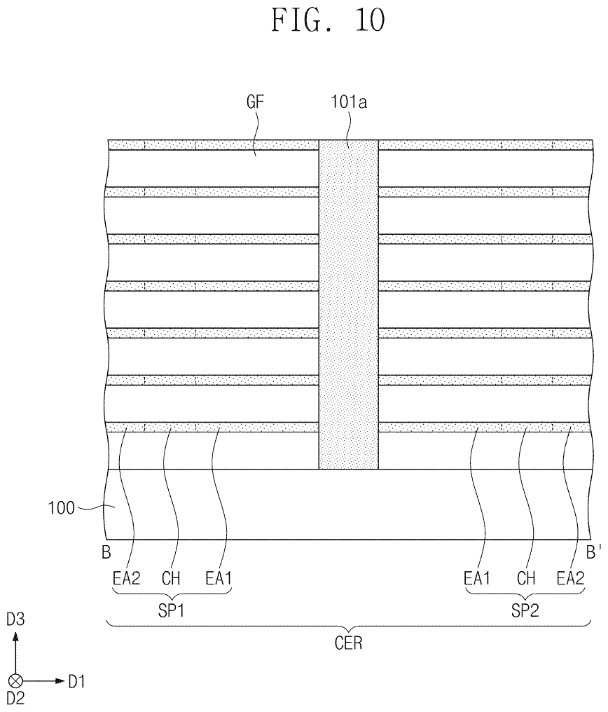

Referring to FIGS. 9 and 10, an etching process of removing a portion of the sacrificial layers SAL and the active layers ACL may be performed. As a result of performing the etching process, the first semiconductor pattern SP1 and the second semiconductor pattern SP2 may be formed to be spaced apart from one another in the first direction D1 from the active layers ACL. The first semiconductor pattern SP1 and the second semiconductor pattern SP2 may each include a first edge portion EA1 and a second edge portion EA2 spaced apart in the first direction D1, and a channel region CH therebetween.

Thereafter, an isolation structure 101 may be formed on a region from which portions of the sacrificial layers SAL and the active layers ACL have been removed. Forming the isolation structure 101 may include filling silicon oxide into the region from which portions of the sacrificial layers SAL and the active layers ACL have been removed.

The isolation structure 101 may include a first isolation structure 101a and a second isolation structure 101b. The first isolation structure 101a and the second isolation structure 101b may be spaced apart from one another in the first direction D1. The first isolation structure 101a and the second isolation structure 101b may each extend in the third direction D3.

Thereafter, the sacrificial layers SAL may be removed, and the gap-fill layer GF may be formed in a region between the first semiconductor patterns SP1 spaced apart in the third direction D3 and a region between the second semiconductor patterns SP2 spaced apart in a third direction D3. Removing the sacrificial layers SAL may include, for example, a wet etch process.

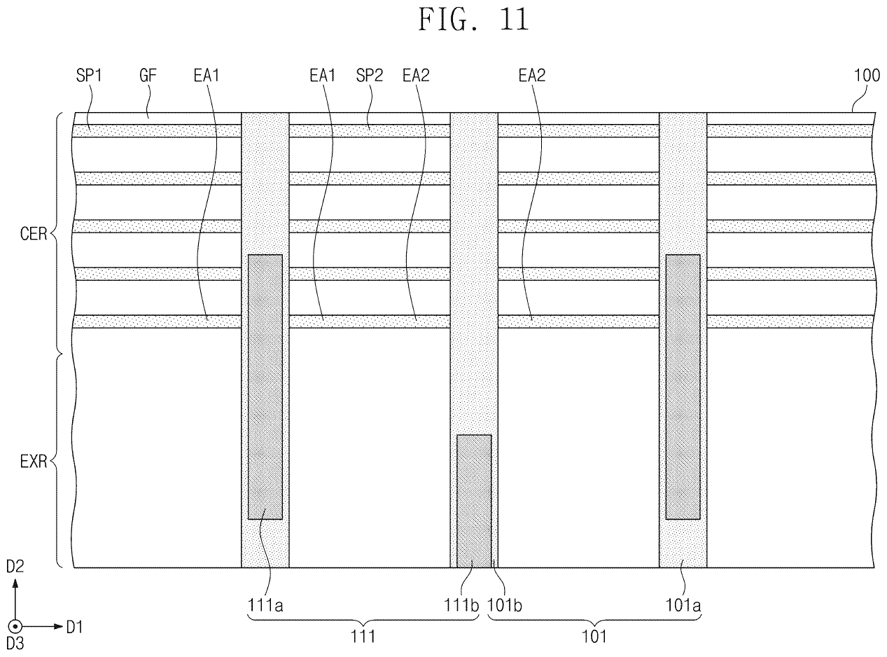

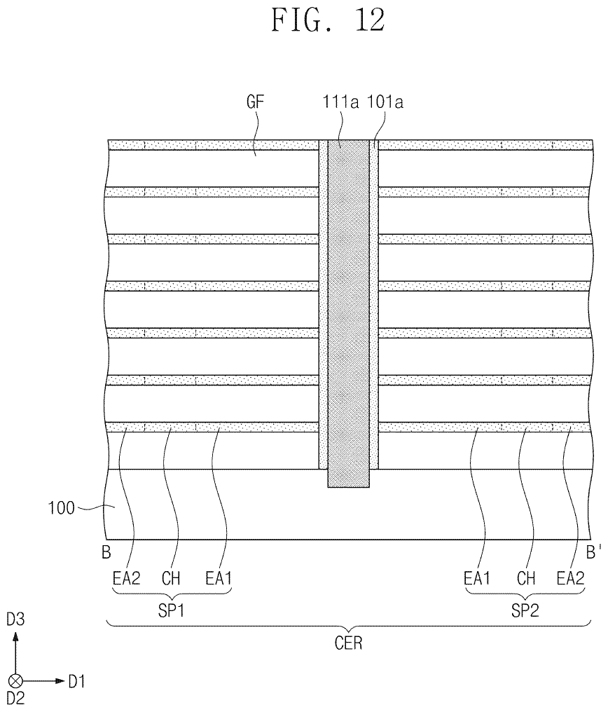

Referring to FIGS. 11 and 12, a shield structure 111 may be formed penetrating the isolation structure 101. Forming the shield structure 111 may include removing a portion of the isolation structure 101 and an upper portion of the substrate 100 and filling silicon nitride on a region where the isolation structure 101, and the upper portion of the substrate 100 are removed. At this time, when a part of the isolation structure 101 and the upper portion of the substrate 100 are removed, the inner surfaces of the isolation structure 101 and one surface of the substrate 100 may be exposed.

The shield structure 111 may extend in the second direction D2 and the third direction D3. The shield structure 111 may include a first shield structure 111a penetrating the first isolation structure 101a and a second shield structure 111b penetrating the second isolation structure 101b.

The first shield structure 111a may be formed along the second direction D2 on the cell array region CER and the extension region EXR. The second shield structure 111b may be formed along the second direction D2 on the extension region EXR.

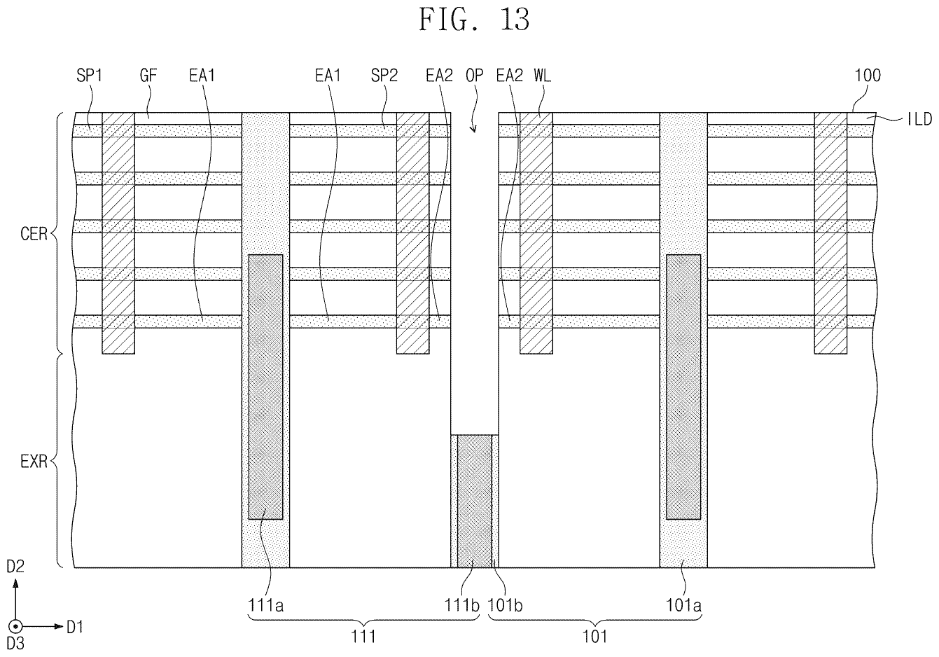

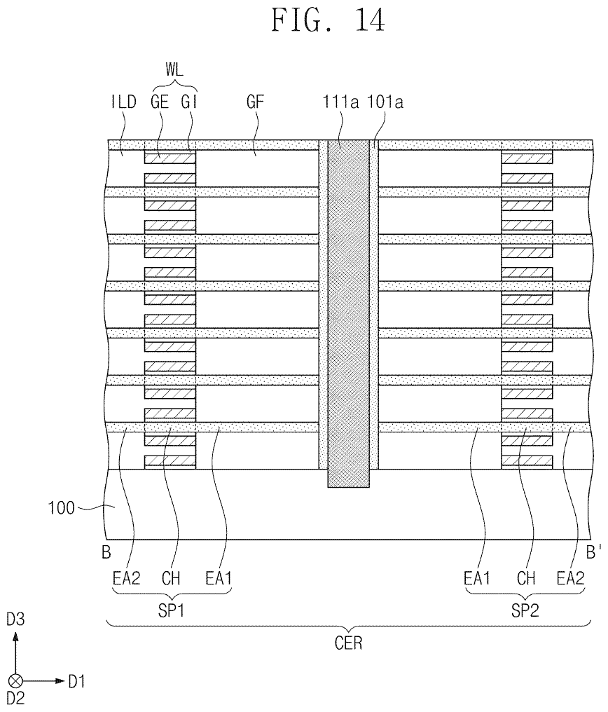

Referring to FIGS. 13 and 14, a portion of the gap-fill layer GF may be removed. At this time, a portion of the second isolation structure 101b on the cell array region CER may be removed together to form an open region OP. According to some embodiments, removing a portion of the second isolation structure 101b may include performing a wet etch process until one end of the second shield structure 111b is exposed.

Then, a word line WL may be formed on the region from which the gap-fill layer GF is removed. The word line WL may be formed between the semiconductor patterns SP. The word line WL may include a gate insulating pattern GI and a gate electrode GE. The gate insulating pattern GI and the gate electrode GE may be formed to cover a portion of the semiconductor pattern SP. In this case, forming the gate electrode GE may include forming a conductive layer and patterning the conductive layer.

In a comparative example, the isolation structure may have voids inside, and when forming a gate electrode on the cell array region CER or performing a cleaning process, a gate electrode materials or chemicals for cleaning may penetrate into the extension region EXR through the voids. However, the second shield structure 111b according to embodiments of the disclosed concepts may fill the inner space of the second isolation structure 101b in the extension region EXR adjacent to the cell array region CER, thereby preventing conductive materials included in the gate electrode GE or chemicals from penetrating the cell array region CER into the extension region EXR.

Thereafter, the interlayer insulating layer ILD may be formed between the gate electrodes GE that are spaced apart from one another. The interlayer insulating layer ILD may extend to the extension region EXR of the substrate 100.

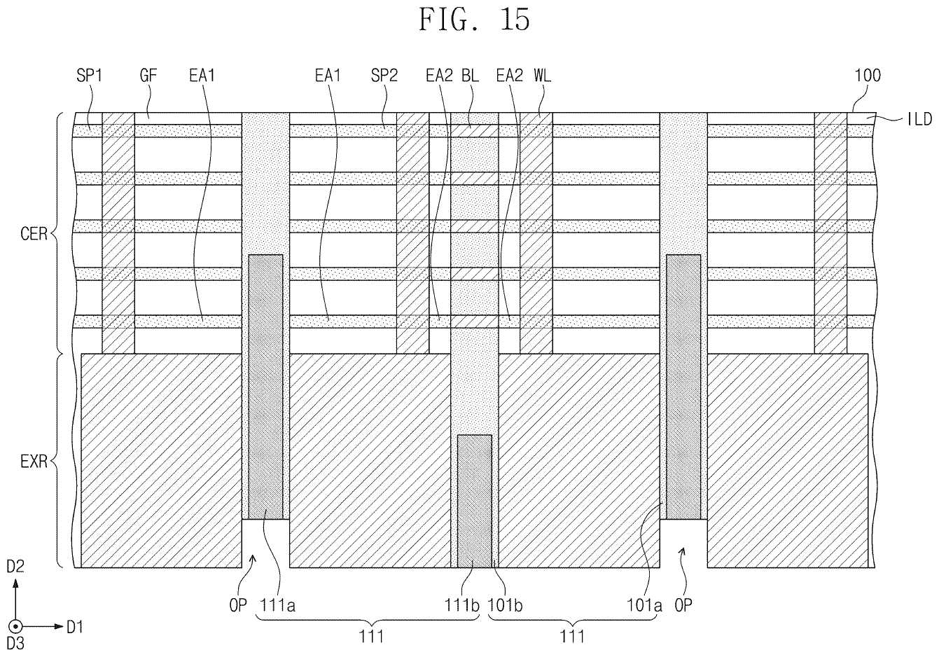

Referring to FIGS. 15, 16, and 17, the second isolation structure 101b removed in FIG. 13 may be re-formed. A bit line BL may be formed through the second isolation structure 101b. As shown in FIG. 16, the bit line BL may be connected to the first edge portions EA1 of the semiconductor patterns SP.

After forming the bit line BL in a partial region of the cell array region CER exposed through the second shield structure 111b, a portion of the extension region EXR may be opened through the first shield structure 111a, and a connection structure SS may be formed.

In some embodiments, a portion of the first isolation structure 101a on the extension region EXR may be removed to form the open region OP. As an example, removing a portion of the first isolation structure 101a may include performing a wet etch process until one end of the first shield structure 111a is exposed. After the gap-fill layer GF is removed through the open region OP to form an empty space, the conductive material may be filled to form a plurality of gate connection lines GL.

In a comparative example, the first isolation structure 101a may have voids inside, and a conductive materials forming the gate connection lines GL or chemical materials for cleaning may penetrate into the cell array region CER through the voids. However, the first shield structure 111a according to embodiments of the disclosed concepts fills the inner space of the first isolation structure 101a in the cell array region CER adjacent to the extension region EXR, thereby preventing conductive materials included in the gate connection lines GL or chemicals from penetrating the extension region EXR into the cell array region CER. The cover insulating layer 120 may be formed on the connection structures SS.

Referring again to FIG. 3, a portion of the removed first isolation structure 101a may be re-formed. Thereafter, a portion of the semiconductor pattern SP and the gap-fill layer GF may be removed to form the capacitor structure CAP. At this time, the first shield structure 111a extending into the first isolation structure 101a may prevent the materials forming the capacitor structure CAP from penetrating from the cell array region CER to the extension region EXR through the voids in the first isolation structure 101a.

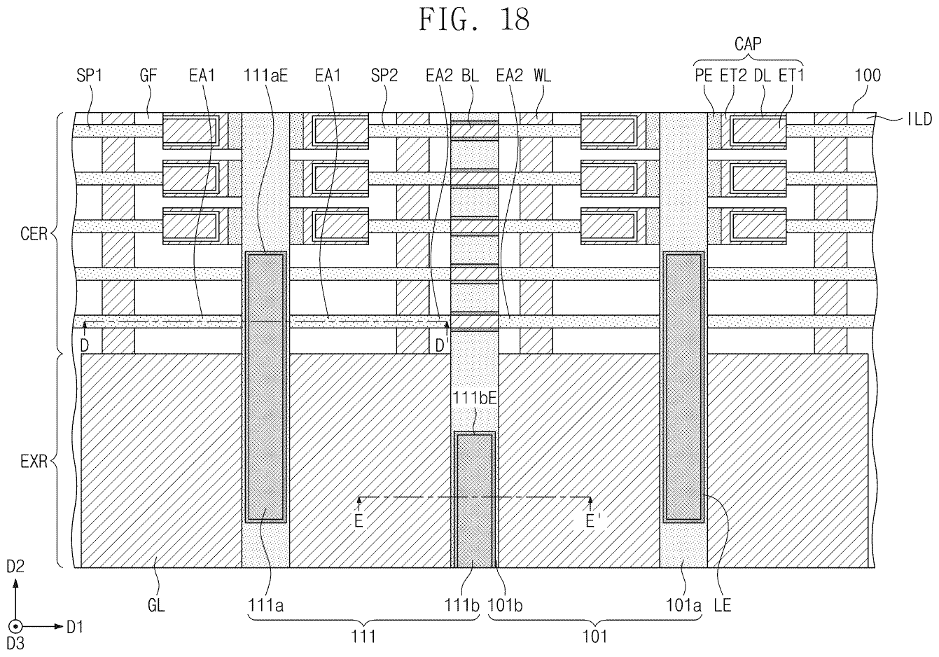

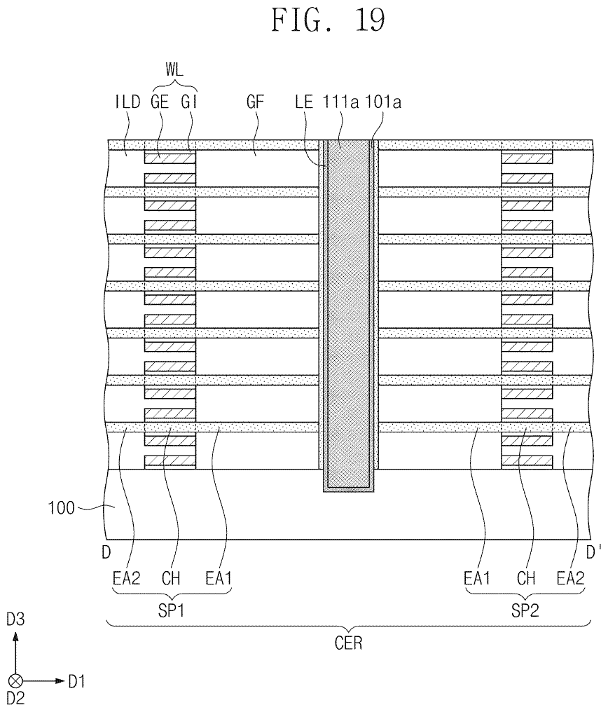

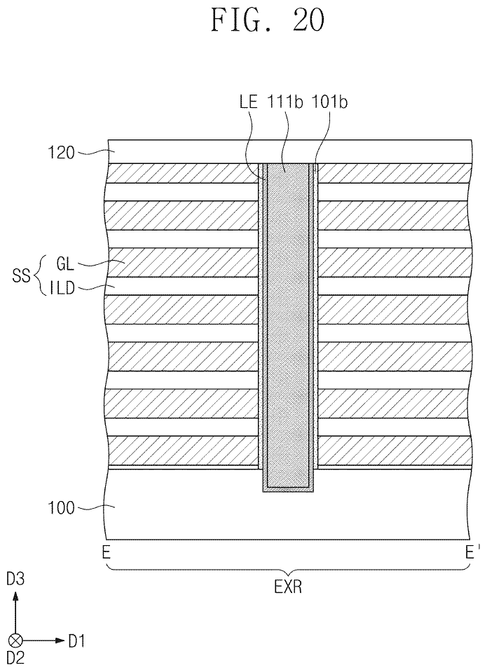

FIG. 18 is a plan view illustrating a cell array region of a three-dimensional semiconductor device according to some embodiments of the disclosed concepts. FIG. 19 is a cross-sectional view taken along line D-D′ of FIG. 18 according to some embodiments of the disclosed concepts. FIG. 20 is a cross-sectional view taken along line E-E′ of FIG. 18 according to some embodiments of the disclosed concepts.

Referring to FIGS. 18 to 20, a three-dimensional semiconductor device according to some embodiments of the disclosed concepts may further include a liner LE surrounding a lower surface and a side surface of each of the first shield structure 111a and the second shield structure 111b. A portion of the liner LE may be provided between the isolation structure 101 and the shield structure 111. A lower portion of the liner LE may be in contact with the substrate 100. That is, the remainder of the liner LE may be provided between the substrate 100 and the shield structure 111. The liner LE may also be provided on the sides of the bit line BL, as shown in FIG. 18.

The liner LE may include the same material as the first isolation structure 101a and the second isolation structure 101b. As an example, the liner LE may include silicon oxide.

In the case of the three-dimensional semiconductor device according to FIGS. 18 to 20, in the processes of FIGS. 11 and 12 described above, the device may be formed by performing a deposition of silicon oxide on the inner walls of the exposed isolation structure 101 and on a surface of the substrate 100, prior to the process of forming the shield structure 111.

A three-dimensional semiconductor device according to embodiments of the disclosed concepts may include an isolation structure provided between semiconductor patterns and a shield structure penetrating therethrough. Here, the shield structure is provided between the cell array region and the extension region, and may include a material having an etch selectivity different from that of the isolation structure.

As a result, the shield structure can prevent materials of components formed on the cell array region from penetrating into the extension region or materials of the components formed on the extension region from penetrating into the cell array region in a manufacturing process of the three-dimensional semiconductor device. As a result, the reliability of the manufacturing process of the three-dimensional semiconductor device is improved, and the electrical characteristics of the three-dimension semiconductor device can be improved and ensured.

While the embodiments of the present invention have been described above with reference to the accompanying drawings, it will be understood by those skilled in the art that the present invention may be embodied in other specific forms without altering the technical spirit or essential features thereof. It is, therefore, to be understood that the embodiments described above are illustrative in all respects and not restrictive.

What is claimed is:

1. A three-dimensional semiconductor device, comprising:
a substrate comprising a cell array region and an extension region;
semiconductor patterns provided on the cell array region of the substrate and extending along a first direction substantially parallel to an upper surface of the substrate;
word lines surrounding the semiconductor patterns and extending along a second direction substantially parallel to the upper surface of the substrate and substantially perpendicular to the first direction;
an isolation structure extending along the second direction on the cell array region and the extension region; and
a shield structure penetrating the isolation structure,
wherein the isolation structure is provided between the semiconductor patterns on the cell array region, and
wherein the isolation structure and the shield structure each includes a material different from one another.

2. The three-dimensional semiconductor device of claim 1, wherein:
the isolation structure comprises silicon oxide, and
the shield structure comprises silicon nitride.

3. The three-dimensional semiconductor device of claim 1, further comprising a gate connection line on the extension region,
wherein at least a portion of the shield structure overlaps the gate connection line in the first direction.

4. The three-dimensional semiconductor device of claim 1, wherein the shield structure has a bar shape extending along the second direction in a plan view.

5. The three-dimensional semiconductor device of claim 1, wherein the shield structure extends through the isolation structure and into the substrate.

6. The three-dimensional semiconductor device of claim 1, further comprising a capacitor structure connected with at least one of the semiconductor patterns,
wherein the shield structure overlaps remaining semiconductor patterns of the semiconductor patterns that are not connected to the capacitor structure in the first direction in a plan view.

7. The three-dimensional semiconductor device of claim 6,
wherein the capacitor structure disposed closest to the extension region is located farther from the extension region than one end of the shield structure located on the cell array region in a plan view.

8. The three-dimensional semiconductor device of claim 1,
wherein:
a plurality of the isolation structure and the shield structure are provided to be spaced apart in the first direction, and
one end of each of the shield structures is aligned in the first direction.

9. The three-dimensional semiconductor device of claim 1, further comprising a bit line connected to one end of each of the semiconductor patterns,
wherein:
the bit line extends along a third direction substantially perpendicular to the upper surface of the substrate, and
the shield structure is provided to be spaced apart from the bit line.

10. A three-dimensional semiconductor device comprising:
a substrate comprising a cell array region and an extension region;
semiconductor patterns provided on the cell array region of the substrate and extending along a first direction substantially parallel to an upper surface of the substrate;
word lines surrounding the semiconductor patterns and extending along a second direction substantially parallel to the upper surface of the substrate and substantially perpendicular to the first direction;
capacitor structures on one side of each of the semiconductor patterns;
bit lines on the other side of each of the semiconductor patterns;
an isolation structure extending along the second direction on the cell array region and the extension region; and
a shield structure penetrating the isolation structure,
wherein at least a part of the shield structure overlaps with the extension region in a plan view.

11. The three-dimensional semiconductor device of claim 10,
wherein:
the isolation structure comprises silicon oxide, and
the shield structure comprises silicon nitride.

12. The three-dimensional semiconductor device of claim 10,
wherein:
the isolation structure includes a first isolation structure and a second isolation structure spaced apart from one another in the first direction,
the shield structure comprises a first shield structure penetrating the first isolation structure and a second shield structure penetrating the second isolation structure, and
the first isolation structure is provided between capacitors spaced apart in the first direction.

13. The three-dimensional semiconductor device of claim 12, wherein a portion of the first shield structure overlaps the word lines in the first direction.

14. The three-dimensional semiconductor device of claim 12, wherein the second shield structure overlaps the bit lines along the second direction.

15. The three-dimensional semiconductor device of claim 12, wherein one end of the first shield structure is located closer to the capacitor structure than one end of the second shield structure.

16. A three-dimensional semiconductor device comprising:
a substrate comprising a cell array region and an extension region;
a semiconductor pattern extending along a first direction substantially parallel to an upper surface of the substrate;
a word line surrounding the semiconductor pattern and extending along a second direction substantially parallel to the upper surface of the substrate and substantially perpendicular to the first direction;
a bit line extending along a third direction substantially perpendicular to the upper surface of the substrate on a first edge portion of the semiconductor pattern;
a capacitor structure on a second edge portion of the semiconductor pattern;
an isolation structure extending along the second direction on the cell array region and the extension region; and
a shield structure penetrating the isolation structure,
wherein:
the isolation structure comprises a first isolation structure provided adjacent to the first edge portion of the semiconductor pattern and a second isolation structure provided adjacent to the second edge portion of the semiconductive pattern,
the shield structure comprises a first shield structure extending into the first isolation structure and a second shield structure extending into the second isolation structure, and
the first isolation structure and the second isolation structure each include a material having an etch selectivity different from that of the first shield structure and the second shield structure.

17. The three-dimensional semiconductor device of claim 16,
wherein:
the first shield structure extends along the second direction on the cell array region and the extension region, and
the second shield structure extends along the second direction on the extension region in a plan view.

18. The three-dimensional semiconductor device of claim 16, further comprising a liner surrounding side surfaces and a lower surface of the first shield structure and the second shield structure.

19. The three-dimensional semiconductor device of claim 16, wherein one end of the first shield structure and one end of the second shield structure are aligned in the first direction.

20. The three-dimensional semiconductor device of claim 18, further comprising a connecting structure on the extension region,
wherein:
the connection structure includes a plurality of gate connection lines and interlayer insulating layers alternately stacked on the substrate,
one end of the first shield structure is located between the capacitor structure and the gate connection line, and
the other end of the first shield structure overlaps the gate connection line in the first direction in a plan view.
